(19) United States
(12) Patent Application Publication
(10) Pub. No.: US 2018/0333740 A1
(43) Pub. Date: Nov. 22, 2018

(54) SPIN DEVICE FOR SEMICONDUCTOR MANUFACTURING PROCESS, MEDICAL DEVICE,PHYSICAL AND CHEMICAL APPLIANCE

(71) Applicant: Hyun Jae LEE, Seoul (KR)

(72) Inventor: Hyun Jae LEE, Seoul (KR)

(21) Appl. No.: 16/061,029

(22) PCT Filed: Dec. 12, 2016
(86) PCT No.: PCT/KR2016/014536

§ 371 Date: Jun. 11, 2018

(30) Foreign Application Priority Data
Dec. 11, 2015 (KR) 10-2015-0177225

(51) Int. Cl. B05C 11/08; H01L 21/02; H01L 21/683; G03F 7/16; H01L 21/67; B05D 1/00

(52) U.S. Cl. CPC B05C 11/08; H01L 21/02; B05D 1/005; G03F 7/162; H01L 21/6715; H01L 21/683

(57) ABSTRACT

A spin device includes a mounting unit on which a wafer is mounted, a control unit configured to generate a control signal for motor driving, a motor configured to spin the mounting unit on which the wafer is mounted, based on the control signal, and a display unit configured to display sectional driving data of the motor and real-time driving information of the motor, wherein the sectional driving data indicating a number of revolutions set for the motor to be driven for each of at least one section, and the real-time driving information is displayed in relation to the sectional driving data when the motor is driven.

### TECHNICAL FIELD

The present disclosure relates to a spin device for semiconductor manufacturing processes, medical devices, and physical and chemical appliances.

### BACKGROUND

A spin-coater refers to a device that pushes a liquid on an object toward the outside using centrifugal force caused by rotation of the object and thus can uniformly coat the liquid on the object. The spin-coater is driven at a speed set for the spin-coater. Thus, it is possible to obtain a result at a user's desired speed. The spin-coater has been used in a photoresist coating process among semiconductor manufacturing processes.

In this regard, Korean Patent Laid-open Publication No. 2005-0106562 discloses a spin-coater and a method of manufacturing a semiconductor device using the same.

Conventionally, a spin-coater has been driven only at a preset speed. Thus, it has been difficult to provide driving information of a motor which can be changed by a user. Further, driving information of the motor in the spin-coater has not been provided to the user in real time. Thus, the user has not been able to actively control a location and a speed of the spin-coater.

### SUMMARY

In view of the foregoing, the present disclosure provides a spin device for semiconductor manufacturing processes, medical devices, and physical and chemical appliances capable of displaying a speed of a motor in graphic or numeric form in real time. Further, the present disclosure provides a spin device for semiconductor manufacturing processes, medical devices, and physical and chemical appliances capable of storing a speed of a motor displayed in graphic or numeric form as a file and providing the file as an attachment. Furthermore, the present disclosure provides a spin device for semiconductor manufacturing processes, medical devices, and physical and chemical appliances capable of driving a motor by reverse spinning of the spin device. However, problems to be solved by the present disclosure are not limited to the above-described problems. There may be other problems to be solved by the present disclosure.

According to an exemplary embodiment of the present disclosure, a spin device may include a mounting unit on which a wafer is mounted, a control unit configured to generate a control signal for motor driving, a motor configured to spin the mounting unit on which the wafer is mounted, based on the control signal, and a display unit configured to display sectional driving data of the motor and real-time driving information of the motor, wherein the sectional driving data indicates a number of revolutions set for the motor to be driven for each of at least one section, and the real-time driving information is displayed in relation to the sectional driving data when the motor is driven.

According to the exemplary embodiment of the present disclosure, wherein the display unit may be configured to display the sectional driving data in a graph and the real-time driving information by a straight bar moving on the graph.

According to the exemplary embodiment of the present disclosure, wherein the display unit may be configured to display the straight bar to be moved in a direction parallel to at least one axis of the graph as the motor is driven.

According to the exemplary embodiment of the present disclosure, wherein the control unit may be configured to set the number of revolutions per unit time of the motor and a driving time of the motor as a vertical axis and a horizontal axis, respectively, of the graph, the display unit displays the straight bar to be moved in a direction parallel to the vertical axis of the graph as the motor is driven and the driving time of the motor is counted, and a point where the graph and the straight bar meet as the straight bar moves refers to the number of revolutions per unit time of the motor at a time point where the straight bar is located.

According to the exemplary embodiment of the present disclosure, wherein the control unit may be configured to generate a control signal for driving the motor in a forward or reverse direction, and the motor is configured to spin the mounting unit in a forward or reverse direction based on the control signal.

According to the exemplary embodiment of the present disclosure, wherein if the motor is driven in the reverse direction, the display unit may be configured to display the sectional driving data and the real-time driving information of the motor differently from a case where the motor is driven in the forward direction.

According to the exemplary embodiment of the present disclosure, wherein the display unit may be configured to display the number of revolutions per unit time of the motor driven in the forward direction as a positive graph and the number of revolutions per unit time of the motor driven in the reverse direction as a negative graph.

According to another exemplary embodiment of the present disclosure, a method of driving a spin device may include generating a control signal for motor driving, spinning a motor based on the control signal, and displaying sectional driving data of the motor and real-time driving information of the motor, wherein the sectional driving data indicates a number of revolutions set for the motor to be driven for each of at least one section, and the real-time driving information is displayed in relation to the sectional driving data when the motor is driven.

The above-described exemplary embodiments are provided by way of illustration only and should not be construed as liming the present disclosure. Besides the above-described exemplary embodiments, there may be additional exemplary embodiments described in the accompanying drawings and the detailed description.

According to the present disclosure, it is possible to provide a spin device for semiconductor manufacturing processes, medical devices, and physical and chemical appliances capable of displaying a speed of a motor in graphic or numeric form in real time. Further, it is possible to provide a spin device for semiconductor manufacturing processes, medical devices, and physical and chemical appliances capable of storing a speed of a motor displayed in graphic or numeric form as a file and providing the file as an attachment. Furthermore, it is possible to provide a spin device for semiconductor manufacturing processes, medical devices, and physical and chemical appliances capable of driving a motor by reverse spinning of the spin device.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram illustrating a spin device for semiconductor manufacturing processes, medical devices, and physical and chemical appliances in accordance with various embodiments described herein.

FIG. 2 is an example diagram illustrating setup data for each section of the spin device in accordance with various embodiments described herein.

FIG. 3A to FIG. 3D are example diagrams provided to explain a process of displaying sectional driving data of a motor and real-time driving information of the motor by moving a straight bar along predetermined sections of the spin device in accordance with various embodiments described herein.

FIG. 4 is a flowchart showing a method of displaying sectional driving data of the motor and real-time driving information of the motor in the spin device in accordance with various embodiments described herein.

### DETAILED DESCRIPTION

Hereafter, embodiments of the present disclosure will be described in detail with reference to the accompanying drawings so that the present disclosure may be readily implemented by those skilled in the art. However, it is to be noted that the present disclosure is not limited to the embodiments but can be embodied in various other ways. In drawings, parts irrelevant to the description are omitted for the simplicity of explanation, and like reference numerals denote like parts through the whole document.

Throughout this document, the term “connected to” that is used to designate a connection or coupling of one element to another element includes both an element being “directly connected” another element and an element being “electronically connected” another element via still another element. Further, it is to be understood that the term “comprises or includes” and/or “comprising or including” used in the document means that one or more other components, steps, operation and/or existence or addition of elements are not excluded in addition to the described components, steps, operation and/or elements unless context dictates otherwise and is not intended to preclude the possibility that one or more other features, numbers, steps, operations, components, parts, or combinations thereof may exist or may be added.

Throughout this document, the term “unit” includes a unit implemented by hardware and/or a unit implemented by software. As examples only, one unit may be implemented by two or more pieces of hardware or two or more units may be implemented by one piece of hardware.

Throughout this document, a part of an operation or function described as being carried out by a terminal or device may be carried out by a server connected to the terminal or device. Likewise, a part of an operation or function described as being carried out by a server may be carried out by a terminal or device connected to the server.

Hereafter, an exemplary embodiment of the present disclosure will be described in detail with reference to the accompanying drawings.

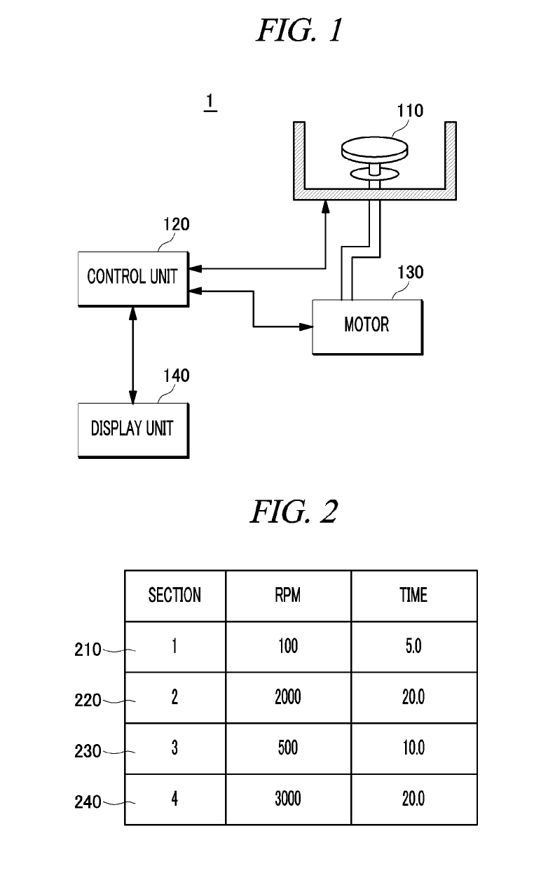

FIG. 1 is a diagram illustrating a spin device for semiconductor manufacturing processes, medical devices, and physical and chemical appliances in accordance with an embodiment of the present disclosure. Referring to FIG. 1, a spin device 1 for semiconductor manufacturing processes, medical devices, and physical and chemical appliances may include a mounting unit 110, a control unit 120, a motor 130, and a display unit 140.

A wafer may be mounted on an upper surface of the mounting unit 110. In this case, the mounting unit 110 is spun by driving of the motor 130, and, thus, the wafer can be spun.

The control unit 120 may generate a control signal for driving the motor 130. In this case, the control unit 120 may generate a control signal for driving the motor 130 in a forward or reverse direction. For example, the control unit 120 may generate a control signal that enables the motor 130 to be driven in a forward direction at 1,000 RPM for a driving time of 10 seconds.

The control unit 120 may set the number of revolutions per unit time of the motor 130 and a driving time of the motor 130 required for display of sectional driving data of the motor 130 and real-time driving information of the motor 130 as a vertical axis and a horizontal axis, respectively, of a graph. For example, the control unit 120 may set a horizontal axis of a graph to represent the number of revolutions per unit time in the range of from 0 RPM to 5,000 RPM and a vertical axis of the graph to represent a driving time of the motor 130 in the range of from 0 sec to 60 sec.

The motor 130 may spin the mounting unit 120 on which the wafer is mounted, based on the control signal. In this case, the motor 130 may spin the mounting unit 110 in a forward or reverse direction based on the control signal. Various kinds of motors such as an AC motor, a DC motor, a BLDC (Brushless DC) motor, and the like may be used as the motor 120.

The display unit 140 may show sectional driving data of the motor 130 and real-time driving information of the motor 130 on a display. Herein, the sectional driving data may indicate a number of revolutions set for the motor 130 to be driven for at least one section, and the real-time driving information may be displayed in relation to the sectional driving data when the motor 130 is driven. In this case, the sectional driving data may be stored in the form of a file and provided in the form of an attachment to a user.

For example, the display unit 140 may show sectional driving data of the motor 130 and real-time driving information of the motor 130 in a text form on the display. For another example, the display unit 140 may show sectional driving data in a graph form and real-time driving information by a straight bar moving on the graph. In this case, the display unit 140 may display the straight bar to be moved in a direction parallel to at least one axis of the graph as the motor 130 is driven. Herein, a point where the graph and the straight bar meet as the straight bar moves may refer to the number of revolutions per unit time of the motor 130 at a time point where the straight bar is located.

The display unit 140 may display the straight bar to be moved in a direction parallel to a vertical axis of the graph as the motor 130 is driven and a driving time of the motor 130 is counted. In this case, if the motor 130 is driven in a reverse direction, the display unit 140 may display sectional driving data and real-time driving information of the motor 130 differently from the case where the motor 130 is driven in a forward direction. For example, the display unit 140 may display the number of revolutions per unit time of the motor 130 driven in the forward direction as a positive graph and the number of revolutions per unit time of the motor 130 driven in the reverse direction as a negative graph.

FIG. 2 is an example diagram illustrating setup data for each section of the spin device in accordance with an embodiment of the present disclosure. Referring to FIG. 2, the spin device 1 may receive RPM information and time for each section preset by a manager and may be driven to spin the mounting unit 110 based on the preset data for each section.

For example, the spin device 1 may receive RPM: 100/time: 5.0 sec for a first section 210, RPM: 2,000/time: 20.0 sec for a second section 220, RPM: 500/time: 10.0 sec for a third section 230, and RPM: 3,000/time: 20.0 sec for a fourth section 240 preset by the user. In this case, the spin device 1 may generate control signals for the respective sections, and the motor 130 may spin the mounting unit 110 on which the wafer is mounted according to a control signal generated based on the preset data for each section.

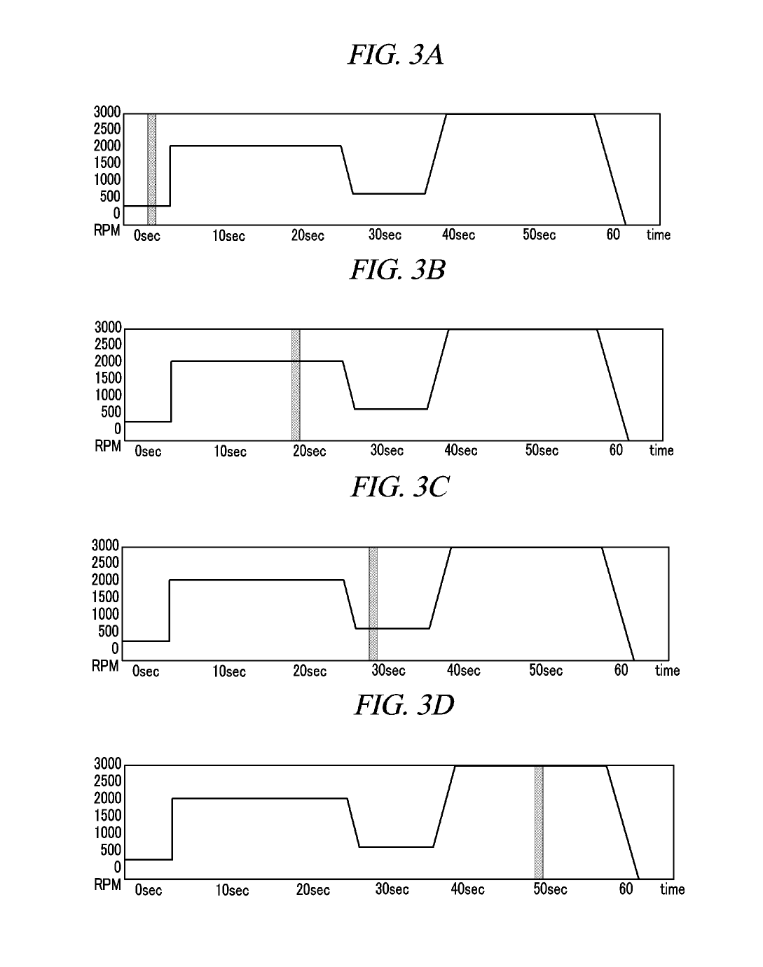

FIG. 3A to FIG. 3D are example diagrams provided to explain a process of displaying sectional driving data of a motor and real-time driving information of the motor by moving a straight bar along predetermined sections of the spin device in accordance with an embodiment of the present disclosure.

The spin device 1 may display sectional driving data of the motor 130 and real-time driving information of the motor 130. Herein, the sectional driving data may indicate a number of revolutions set for the motor 130 to be driven for at least one section, and the real-time driving information may be displayed in relation to the sectional driving data when the motor 130 is driven. To this end, the spin device 1 may set the number of revolutions per unit time (RPM) of the motor 130 and a driving time of the motor 130 as a vertical axis and a horizontal axis, respectively, of a graph. For example, the spin device 1 may set a vertical axis of a graph to represent the number of revolutions per unit time of the motor 130 and a horizontal axis of the graph to represent a driving time of the motor 130 based on the number of revolutions per unit time of the motor 130 and a driving time of the motor 130 preset for each section.

The spin device 1 may display a straight bar to be moved in a direction parallel to the vertical axis of the graph as the motor 130 is driven and a driving time of the motor 130 is counted.

FIG. 3A is an example diagram displaying sectional driving data of the motor 130 and real-time driving information of the motor 130 with respect to a first section of the spin device. Referring to FIG. 2 and FIG. 3A, if the first section of the spin device 1 is set to RPM: 100/time: 5.0 sec by the user, the spin device 1 may display sectional driving data as RPM: 100 during a driving time from 0 sec to 5.0 sec. In this case, the spin device 1 may display real-time driving information for the first section by moving the straight bar.

FIG. 3B is an example diagram displaying sectional driving data of the motor 130 and real-time driving information of the motor 130 with respect to a second section of the spin device. Referring to FIG. 2 and FIG. 3B, if the second section of the spin device 1 is set to RPM: 2,000/time: 20.0 sec by the user, the spin device 1 may display sectional driving data as RPM: 2,000 during a driving time from 5.0 sec to 25.0 sec. In this case, the spin device 1 may display real-time driving information for the second section by moving the straight bar.

FIG. 3C is an example diagram displaying sectional driving data of the motor 130 and real-time driving information of the motor 130 with respect to a third section of the spin device. Referring to FIG. 2 and FIG. 3C, if the third section of the spin device 1 is set to RPM: 500/time: 10.0 sec by the user, the spin device 1 may display sectional driving data as RPM: 500 during a driving time from 25.0 sec to 35.0 sec. In this case, the spin device 1 may display real-time driving information for the third section by moving the straight bar.

FIG. 3D is an example diagram displaying sectional driving data of the motor 130 and real-time driving information of the motor 130 with respect to a fourth section of the spin device. Referring to FIG. 2 and FIG. 3D, if the fourth section of the spin device 1 is set to RPM: 3,000/time: 20.0 sec by the user, the spin device 1 may display sectional driving data as RPM: 3,000 during a driving time from 35.0 sec to 55.0 sec. In this case, the spin device 1 may display real-time driving information for the fourth section by moving the straight bar.

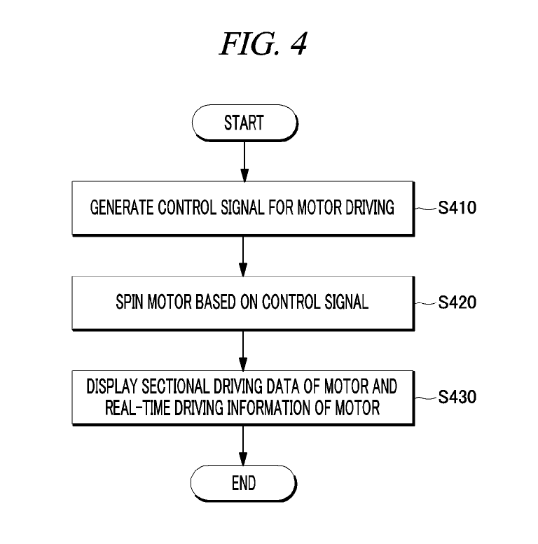

FIG. 4 is a flowchart showing a method of displaying sectional driving data of the motor and real-time driving information of the motor in the spin device in accordance with an embodiment of the present disclosure. A method of displaying sectional driving data of the motor and real-time driving information of the motor which is performed by the spin device 1 according to the embodiment illustrated in FIG. 4 includes the processes time-sequentially performed by the spin device 1 according to the embodiment illustrated in FIG. 1 to FIG. 3D. Therefore, the above descriptions of the spin device 1 according to the embodiment illustrated in FIG. 1 to FIG. 3D may be applied to the method of displaying sectional driving data of the motor and real-time driving information of the motor according to the embodiment illustrated in FIG. 4, even though they are omitted hereinafter. In a process S410, the spin device 1 may generate a control signal for motor driving. For example, the spin device 1 may generate a control signal for driving a motor in a forward or reverse direction. In a process S420, the spin device 1 may spin the motor based on the control signal. For example, the spin device 1 may spin the motor in the forward or reverse direction based on the control signal. In a process S430, the spin device 1 may display sectional driving data of the motor and real-time driving information of the motor. Herein, the sectional driving data may indicate a number of revolutions set for the motor to be driven for at least one section, and the real-time driving information may be displayed in relation to the sectional driving data when the motor is driven. For another example, the spin device 1 may show sectional driving data in a graph form and real-time driving information as a straight bar moving on the graph.

In the descriptions above, the processes S410 to S430 may be divided into additional processes or combined into fewer processes depending on an embodiment. In addition, some of the processes may be omitted and the sequence of the processes may be changed if necessary.

The spin device for semiconductor manufacturing processes, medical devices, and physical and chemical appliances described above with reference to FIG. 1 to FIG. 4 can be implemented in a computer program stored in a medium to be executed by a computer or a storage medium including instructions codes executable by a computer. Also, the spin device for semiconductor manufacturing processes, medical devices, and physical and chemical appliances described above with reference to FIG. 1 to FIG. 4 can be implemented in a computer program stored in a medium to be executed by a computer. A computer-readable medium can be any usable medium which can be accessed by the computer and includes all volatile/non-volatile and removable/non-removable media. Further, the computer-readable medium may include all computer storage and communication media. The computer storage medium includes all volatile/non-volatile and removable/non-removable media embodied by a certain method or technology for storing information such as computer-readable instruction code, a data structure, a program module or other data. The communication medium typically includes the computer-readable instruction code, the data structure, the program module, or other data of a modulated data signal such as a carrier wave, or other transmission mechanism, and includes a certain information transmission medium.

The above description of the present disclosure is provided for the purpose of illustration, and it would be understood by those skilled in the art that various changes and modifications may be made without changing technical conception and essential features of the present disclosure. Thus, it is clear that the above-described embodiments are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

We claim:

1. A spin device, comprising:
a mounting unit on which a wafer is mounted;
a control unit configured to generate a control signal for motor driving;
a motor configured to spin the mounting unit on which the wafer is mounted, based on the control signal; and
a display unit configured to display sectional driving data of the motor and real-time driving information of the motor,
wherein the sectional driving data indicates a number of revolutions set for the motor to be driven for each of at least one section, and
the real-time driving information is displayed in relation to the sectional driving data when the motor is driven.

2. The spin device of claim 1,
wherein the display unit is configured to display the sectional driving data in a graph and the real-time driving information by a straight bar moving on the graph.

3. The spin device of claim 2,
wherein the display unit is configured to display the straight bar to be moved in a direction parallel to at least one axis of the graph as the motor is driven.

4. The spin device of claim 3,
wherein the control unit is configured to set the number of revolutions per unit time of the motor and a driving time of the motor as a vertical axis and a horizontal axis, respectively, of the graph,
the display unit displays the straight bar to be moved in a direction parallel to the vertical axis of the graph as the motor is driven and the driving time of the motor is counted, and
a point where the graph and the straight bar meet as the straight bar moves refers to the number of revolutions per unit time of the motor at a time point where the straight bar is located.

5. The spin device of claim 1,
wherein the control unit is configured to generate a control signal for driving the motor in a forward or reverse direction, and
the motor is configured to spin the mounting unit in a forward or reverse direction based on the control signal.

6. The spin device of claim 5,
wherein if the motor is driven in the reverse direction, the display unit is configured to display the sectional driving data and the real-time driving information of the motor differently from a case where the motor is driven in the forward direction.

7. The spin device of claim 6,
wherein the display unit is configured to display the number of revolutions per unit time of the motor driven in the forward direction as a positive graph and the number of revolutions per unit time of the motor driven in the reverse direction as a negative graph.

8. A method of driving a spin device, comprising:
generating a control signal for motor driving;
spinning a motor based on the control signal; and
displaying sectional driving data of the motor and real-time driving information of the motor,
wherein the sectional driving data indicates a number of revolutions set for the motor to be driven for each of at least one section, and
the real-time driving information is displayed in relation to the sectional driving data when the motor is driven.

9. The method of driving a spin device of claim 8,
wherein in the displaying of the sectional driving data and the real-time driving information, the sectional driving data are displayed in a graph and the real-time driving information is displayed as a straight bar moving on the graph.

10. The method of driving a spin device of claim 8,
wherein in the generating of the control signal, a control signal for driving the motor in a forward or reverse direction is generated, and
in the spinning of the motor, the motor is spun in a forward or reverse direction based on the control signal.
